(19) United States
(12) Patent Application Publication
(10) Pub. No.: US 2025/0383378 A1
(43) Pub. Date: Dec. 18, 2025

(54) NON-CONTACT VOLTAGE SENSING

(71) Applicant: Analog Devices International Unlimited Company, Limerick (IE)

(72) Inventor: Jonathan Ephraim David Hurwitz, Edinburgh (GB)

(21) Appl. No.: 19/239,500

(22) Filed: Jun. 16, 2025

Related U.S. Application Data
(60) Provisional application No. 63/660,935, filed on Jun. 17, 2024.

(51) Int. Cl. G01R 19/165

(52) U.S. Cl. CPC G01R 19/16547; G01R 19/16576

(57) ABSTRACT

Non-contact AC voltage sensing systems, methods and circuits are described. An example comprises a conductive sense component for positioning, when in use, in non-contacting proximity to a conductor to capacitively couple with the conductor to generate an AC sensing signal at the conductive sense component, wherein the AC sensing signal is dependent on an AC voltage of the conductor. The system also comprises a comparator comprising: a first input coupled to the conductive sense component, a second input, and an output to output a first comparison signal indicative of which of a first potential at the first input and a second potential at the second input is higher. Either input of the comparator is biased by a variable reference voltage. The system comprises an analysis circuit coupled to the output of the comparator and configured to sense the AC voltage based on the variable reference voltage and the comparison signal.

### CLAIM OF PRIORITY

This application claims priority from U.S. provisional patent application No. 63/660,935 filed on 17 Jun. 2024, which is incorporated herein by reference in its entirety.

### TECHNICAL FIELD

The present disclosure relates to methods, circuits and systems for non-contact voltage sensing.

### BACKGROUND

Sensing voltages may take many different forms, including simply sensing whether or not a voltage is present, characterising the phase of the voltage (for example relative to other sensed voltages), and/or characterising the magnitude of the voltage (such as determining the peak voltage, the average voltage, the RMS voltage, etc.).

Detecting whether or not a voltage is present may be used for a number of purposes. In one example, it may be used for safety monitoring, before releasing a function like turning on a device or circuit breaker. In another example it may be used for diagnostics to determine whether a lack of detected current is because of a broken/detached power cable, or because the driven device has been turned off. In another example, if there is a circuit breaker, it may be used to determine whether a lack of detected current is because the circuit breaker has tripped or because the driven device has been turned off.

Characterising the phase and/or magnitude of the voltage may also be used for a number of purposes. For example, it may be used to synchronise different sources (such as an inverter phase and/or magnitude) before connecting to another source, such as the electrical grid. In another example, it may be used for reporting back voltage, and/or power/energy consumption when combined with associated current measurements.

Voltage measurement techniques often require a direct electrical connection to the current carrying conductor (i.e., a galvanic connection). However, in some situations this is not possible, or is inconvenient. For example, access for a galvanic connection may not be available, or the voltages may be very high (for example, in the 100s or 1000s of volts), requiring costly isolation between high and low voltage sides of the measurement circuit. In such circumstances, non-contact voltage sensing systems are useful. In a non-contact voltage sensing system, there is no direct electrical connection (i.e., no galvanic contact) between the conductor carrying the signal being sensed and the circuitry performing the sensing. Instead of a galvanic contact, a conductive sensing component may be positioned in non-contacting proximity to the conductor carrying the signal to be sensed (e.g., positioned on, or near, an insulator that encases the conductor carrying the signal to be sensed), to form a capacitive coupling with the conductor carrying the signal to be sensed. Any changes in the signal being carried by the conductor should induce a signal in the conductive sensing component, as a result of the capacitive coupling, which can then be sensed by circuitry connected to the conductive sensing component.

### SUMMARY

In a first aspect of the disclosure there is provided a non-contact AC voltage sensing system comprising: a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor; a first comparison circuit comprising: a first comparator comprising: a first input coupled to the first conductive sense component; a second input, wherein either input of the first comparator is biased by a variable reference voltage applied to the first comparison circuit; and an output to output a first comparison signal indicative of which of a first potential at the first input and a second potential at the second input is higher; and an analysis circuit coupled to the output of the first comparator and configured to sense the first AC voltage based on the variable reference voltage and the first comparison signal.

In a second aspect of the disclosure, there is provided a method for sensing an AC voltage, the method comprising: comparing a first potential at a first input of a comparator against a second potential at a second input of the comparator in order to generate a comparison signal indicative of which of a first potential at the first input and a second potential at the second input is higher, wherein the first input of the comparator is coupled to a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor, and wherein either the first input of the comparator or the second input of the comparator is biased by a variable reference voltage, and the method further comprises: sensing the first AC voltage based on the variable reference voltage and the first comparison signal.

In a third aspect of the present disclosure there is provided a circuit comprising: a comparison circuit comprising: a comparator comprising: a first input suitable for coupling to a conductive sense component, wherein the conductive sense component is suitable for capacitive coupling to a conductor having an AC voltage; a second input, wherein the first input or the second input is biased by a variable reference voltage applied to the comparison circuit; and an output to output a comparison signal indicative of which of a first potential at the first input and a second potential at the second input is higher; and an analysis circuit coupled to the output of the comparator and configured to: set the variable reference voltage; and sense the AC voltage based on the variable reference voltage and the comparison signal.

### BRIEF DESCRIPTION OF THE DRAWINGS

Aspects of the present disclosure are described, by way of example only, with reference to the following drawings, in which:

FIG. 1 shows an example poly-phase energy measurement system;

FIG. 2A shows an example top-down view of a conductive sense component and PCB with a central opening through which a conductor passes;

FIG. 2B shows a side-on view of the arrangement of FIG. 2A;

FIG. 3A shows an example non-contact AC voltage sensing system;

FIG. 3B shows a representation of how Cout changes with Vdiv for the system of FIG. 3A;

FIG. 4A shows a further example non-contact AC voltage sensing system;

FIG. 4B shows a representation of how Cout changes with Vdiv for the system of FIG. 4A;

FIG. 5 shows a further example non-contact AC voltage sensing system;

FIG. 6 shows a further example non-contact AC voltage sensing system;

FIG. 7 shows a representation of the AC signal Vdiv of FIG. 6 and three different reference voltage levels, Vref1, Vref2 and Vref3;

FIGS. 8A, 8B and 8C show the application of Vref1, Vref2 and Vref3 at different times;

FIGS. 9A and 9B show reconstructed voltages;

FIG. 10A shows a further example non-contact AC voltage sensing system;

FIG. 10B shows a representation of how Cout changes with Vdiv for different bias voltages for the system of FIG. 10A;

FIG. 11 shows a further example non-contact AC voltage sensing system;

FIG. 12A shows a further example non-contact AC voltage sensing system;

FIG. 12B shows a representation of Vdiv after application of Vbias in the system of FIG. 12A;

FIG. 13 shows a further example non-contact AC voltage sensing system;

FIG. 14 shows a further example non-contact AC voltage sensing system;

FIG. 15 shows a further example non-contact AC voltage sensing system;

FIG. 16 shows a further example non-contact AC voltage sensing system;

FIG. 17 shows a further example non-contact AC voltage sensing system; and

FIG. 18 shows steps of an example method of sensing an AC voltage.

### DETAILED DESCRIPTION

This relates to non-contact AC voltage sensing systems, methods and circuits that sense an AC voltage using a conductive sense component positioned near a conductor to generate an AC sensing signal. The AC sensing signal is then evaluated by a comparison circuit against a variable reference voltage.

By comparing against a variable reference voltage it may be possible to sense various different characteristics, such as magnitude, phase and/or frequency, of the AC voltage at relatively low cost and complexity. For example, it is possible to generate a reconstruction of an AC signal that is dependent on the AC voltage such that analysis of the AC voltage phase/frequency/magnitude may be performed, without requiring complex circuits and operation, higher power consumption, more expensive components, higher data requirements, etc.

The disclosed non-contact voltage sensing systems, circuits and methods may be particularly beneficial for applications such as energy monitoring and measurement in complex power systems, such as multi-phase systems, where knowing the voltage characteristics may be helpful for load balancing, diagnostics, and safety monitoring.

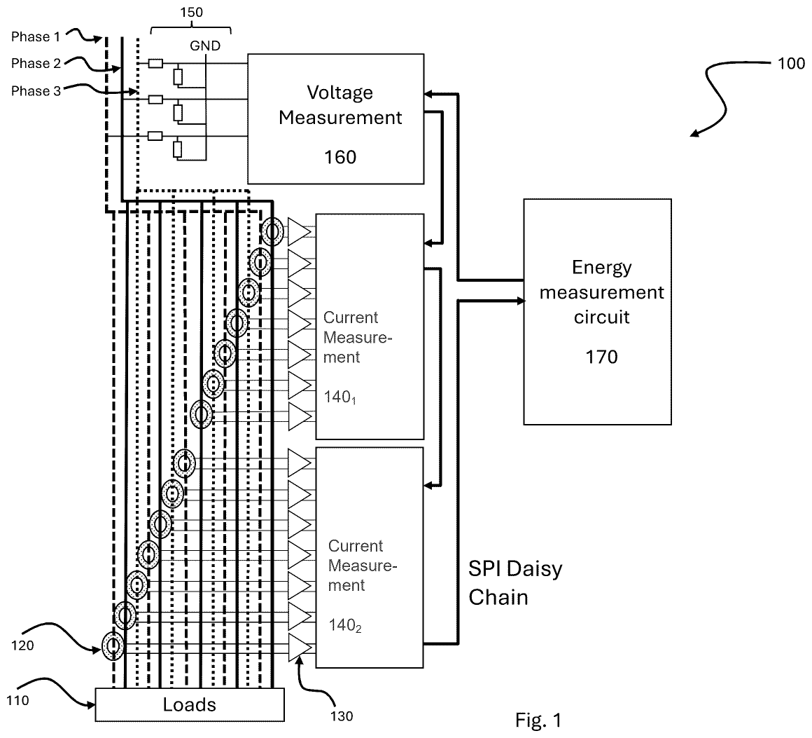

FIG. 1 shows an example poly-phase energy measurement system 100 The system 100 comprises a three phase voltage supply—phase 1, phase 2 and phase 3—from each of which are multiple branches each potentially serving at least one load within the loads 110. There are various uses of such systems, for example for metering in Electric Vehicle Supply Equipment (EVSE) or motor drive, or for power distribution units, etc.

For each branch there is a current transducer, for example a current transformer or a rate of change of current sensor (di/dt current sensor) such as a Rogowski coil. In this example, the current transducers are non-contact current sensors, which has the benefit of more straightforward installation on each of the branches and may reduce cost/complexity if the voltages on each branch are likely to be high enough to require isolation mechanisms between a galvanic contact and the current measurement circuitry. However, the current transducers 120 could alternatively be of any other type, such as shunts.

The system 100 also comprises an optional buffer 130 for the current measurement signal derived from each current transducer 120, and current measurement circuitry 1401 and 1402, for generating a measurement of current. In this particular implementation, the current measurement circuitry is divided across two dies/chips, but in an alternative it may be implemented in a single die/chip, or divided across three or more dies/chips. Also in this particular implementation, the current measurement circuitry 1401 and 1402 is connected together, and to the energy measurement unit 170, with SPI daisy chaining, but any alternative communication coupling may be used. The current measurement circuitry 1401 and 1402 is configured to output digital signals to the energy measurement unit 170, indicative of each current measurement.

The system 100 also comprises circuitry for measuring each phase voltage. In this example, the circuitry comprises optional potential dividers 150 arranged to form a galvanic connection to each phase, and divide the voltage down. The circuitry also comprises a voltage measurement circuit 160 configured to measure the divided down voltage and output digital signals to the energy measurement unit 170 (via the SPI daisy chaining, in this particular example) indicative of the measured voltages. The voltage measurement circuit 160 may comprise isolation functionality to isolate the relatively high voltage, hot side, which is coupled to the potential dividers 150, from the relatively low voltage digital interface. Such circuitry may be practical for measuring voltages of the three phase supply, but not practical or cost efficient for measuring voltage of all the branches from each phase, particularly where there are a very large number of branches from each phase.

The energy measurement unit 170 may comprise any suitable functionality for energy measurement/metrology using the received voltage and current measurement digital signals and/or for controlling the current measurement circuits 1401 and 1402 and the voltage measurement circuit 160.

The system 100 is configured for energy measurement and the inventors have recognised that it may be beneficial for such systems to have a voltage sensing capability for at least some of the branches, in order to provide further functionality. For example, some or all of the branches may include a circuit breaker and sensing the voltage on a branch may be helpful for determining the status of the branch, for example whether the circuit breaker is open, or if the circuit breaker is closed and a load is being driven, or if the circuit breaker is closed and the load is disconnected/off. Furthermore, it may be desirable to sense voltage characteristics such as magnitude and/or phase on some or all of the branches for various different purposes. For example, a load may be connected to a branch at any time, or a load may turn on at any time. Prior to that, it may be helpful to understand the magnitude and/phase of the voltage to which the load will be connected, for example for load balancing and/or phase synchronisation between the branch and the load being connected. As a result, it can be seen there are a wide variety of different reasons, including safety monitoring, diagnostics, load balancing, load synchronisation, energy measurement, etc., why it may be helpful to sense the voltage on some or all of the branches.

As explained in the ‘background’ section, in many situations, non-contact voltage sensing has advantages over galvanic contact voltage measurement. The inventors have recognised that in arrangements where there is already a current transducer in place, particularly a PCB implemented current transducer such as a PCB implemented Rogowski coil, non-contact voltage sensing capabilities may be added relatively easily.

As the skilled person will understand, a di/dt current transducer such as a Rogowski coil may be implemented on a PCB by at least partially surrounding an opening/hole in the PCB with a coil formed by PCB conductive traces and vias. A conductor (e.g., a conductive wire or rod) carrying the current to be sensed may be passed through the opening/hole in the PCB and any changes in the current carried by the conductor may be sensed by the di/dt transducer. The inventors have recognised that in this case, the PCB presents a convenient surface on which to position a conductive sense component for use in non-contact sensing the voltage of the conductor.

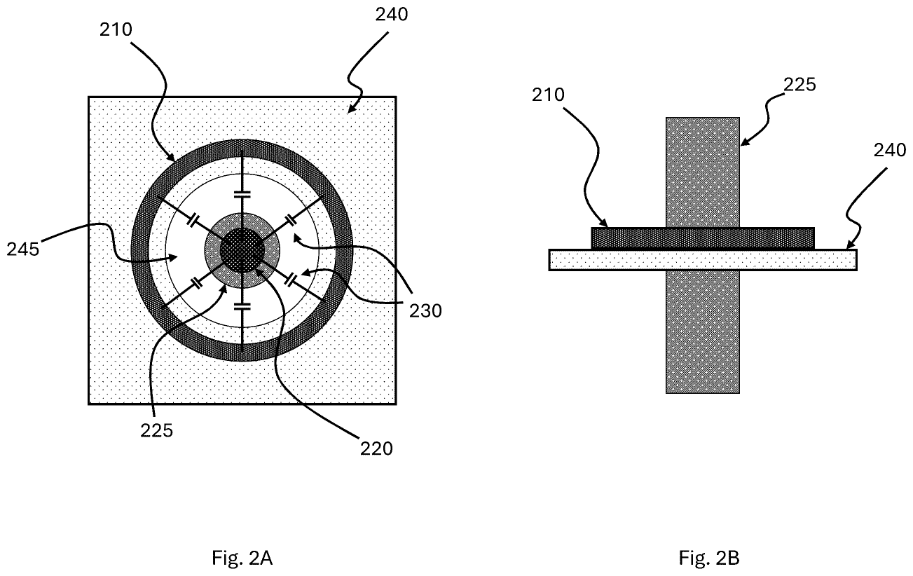

FIG. 2A shows an example top-down view of a PCB 240 with a central opening through which a conductor 220 passes. The conductor 220 is coated with an insulator 225.

FIG. 2B shows the same arrangement, but from a side-on view.

The PCB 240 includes a di/dt current transducer (such as a Rogowski coil) for current measurement purposes, although that is not represented in the Figures for the sake of simplicity. A ring-shaped conductive sense component 210 is position on the surface of the PCB 240 so as to completely surround the conductor 220 and capacitively 230 couple with the conductor 220. The capacitors 230 represented in FIG. 2A are not capacitor components but instead represent the capacitive coupling formed between the conductor 220 and the conductive sense component 210, where the conductor 220 forms one plate of the “capacitor”, the conductive sense component 210 the other plate of the “capacitor”, and the insulating material therebetween (in this example, air and the insulator 225) form the dielectric of the “capacitor”. As a result, an AC voltage of the conductor 220 will generate an AC sensing signal in the conductive sense component 210. Changes in the phase and/or magnitude of AC voltage will cause a corresponding change in the AC sensing signal. As such, the AC sensing signal can be used to sense the AC voltage.

FIGS. 2A and 2B show the conductive sense component 210 as a substantially circular ring, positioned on a PCB and fully surrounding the conductor 220. This shape may have a benefit of causing the coupling capacitance between the conductive sense component 210 and the conductor 220 to be relatively constant regardless of the position of the conductor 220 within the circle. However, this is merely one example. In an alternative, the conductive sense component 210 may only partially surround the conductor 220, for example being a split ring, or may be of a completely different shape, such as a rectangular plate that is simply positioned in proximity to a part of the conductor 220. Alternatively, it could be a series of plates arranged around the conductor 220, or a planar structure like a ruff/collar, formed as a separate piece or built into the PCB 240. In some examples it could be part of the internal edge of the PCB 240 (for example, plating the edge of the hole through which the conductor 220 passes, or formed as a series of conductive vias surrounding the hole through which the conductor 220 passes). Furthermore, regardless of the shape of the conductive sense component 210, it could be held in non-contacting proximity to the conductor 220 in any other suitable way. Furthermore, any insulating material may be present between the conductive sense component 210 and the conductor 220, including (but not limited to) air and/or an insulating material coating the conductor 220. For example, the conductive sense component 210 may be configured to be attached directly to the outer surface of the insulator 225. Regardless, the non-contacting AC voltage sensing systems and methods described below are applicable to all designs and installations of conductive sense component 210, provided the conductive sense component 210 is suitable for positioning in non-contacting proximity to the conductor 220 so as to capacitively couple with the conductor 220.

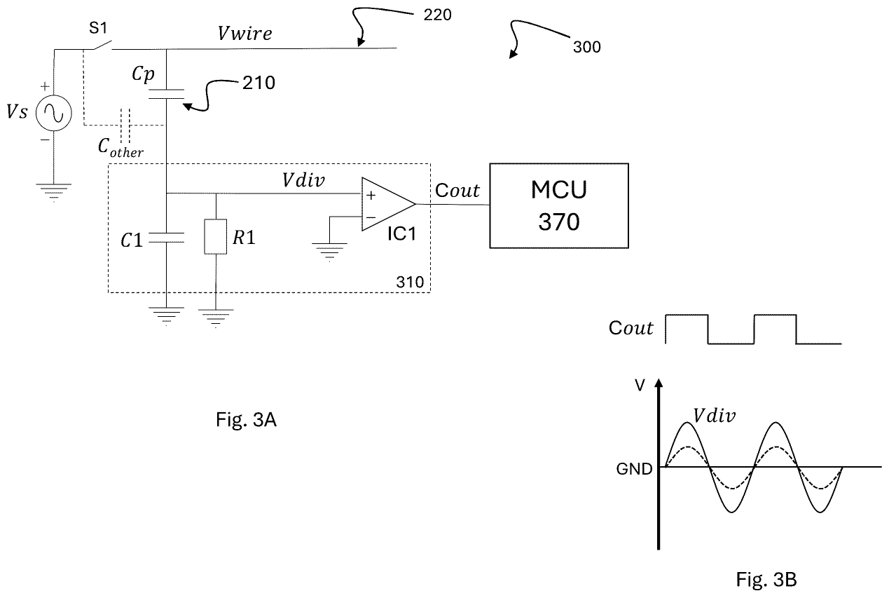

FIG. 3A shows an example non-contact AC voltage sensing system 300. The system 300 is configured to sense a voltage, Vwire, of the conductor 220. The conductor 220 is coupled to an AC source, Vs, via an optional switch S1, which may be a circuit breaker. The conductive sense component 210 is positioned in non-contacting proximity to the conductor 220 so as to capacitively couple with the conductor 220. That capacitive coupling is represented in FIG. 3A by the capacitor Cp (which is the same as the capacitive coupling 230 shown in FIG. 2A), with the conductive sense component 210 acting as one plate of the capacitor Cp and the conductor 220 acting as the other plate of the capacitor Cp. Also represented as Cother is further capacitive coupling, which may or may not be present between the conductive sense component 210 and other conductors in its vicinity, for example conductors carrying other phase voltages. In some installations Cother may be very small, or zero, and in others is may be more significant.

The system 300 comprises a comparison circuit 310 made up of capacitor C1, resistor R1 and comparator IC1. Capacitor C1 may be a discrete component, or may be the input impedance of the comparator IC1. The capacitor C1 and resistor R1 are coupled in parallel, and in alternative implementations the comparison circuit 310 may comprise only one of the capacitor C1 and the resistor R1. The resistor R1 may ensure that Vdiv remains referenced to the ground reference of the comparator IC1 (e.g., the reference voltage to which R1 is coupled, in this example ground, may set the DC level for Vdiv). The capacitor C1 and the resistor R1 may be collectively referred to as an impedance component Z1, as follows:

$$Z 1 = \frac{1}{\frac{1}{C 1} + \frac{1}{R 1}}$$

Alternatively, it only resistor R1 is present, then Z1=R1, and it only the capacitor C1 is present, then Z1=C1.

As a result, Vdiv may be expressed as:

$$Vdiv = \frac{Cp}{Cp + Z 1} Vwire$$

In this expression, Cother is assumed to be zero, but the skilled person will appreciate that for non-zero values of Cother, each instance of “Cp” in the above may be replaced by “Cp+Cother”.

The values of C1 and R1 may be chosen such that for the expected range of likely Vwire values, Vdiv should fall within the allowable input range of the comparator IC1.

In a further alternative implementation, rather than C1 and R1 both being coupled to the same reference voltage (in this example, ground), they may each be connected to different reference voltages, such as one being coupled to ground and the other to some other reference voltage.

In the example of FIG. 3A, the capacitor C1 and/or resistor R1 are each coupled at one side (i.e., at a first terminal) to the conductive sense component 210 and at the other side (i.e., at a second terminal) to ground. The capacitive coupling Cp, and the capacitor C1 and/or the resistor R1, together form an impedance divider to divide Vwire down to a smaller voltage Vdiv, which is dependent on Vwire (e.g., if Vwire changes, Vdiv should also change), so that Vwire can be sensed with low voltage circuitry. In this example implementation, the impedance divider also sets the DC level of the circuit to ground.

A first input of the comparator IC1 (in this example the non-inverting input, but in an alternative it could be the inverting input) is coupled to the conductive sense component 210 (i.e., to the mid-node of the impedance divider). A second input of the comparator IC1 (in this example the inverting input, but in alternative it could be the non-inverting input) is coupled to ground. As a result, the comparator IC1 compares the potential at the first input (e.g., Vdiv) against the potential at the second input (e.g., ground). When Vdiv is greater than ground, the comparator output Cout goes high (e.g., to 5V, or 12V, etc., depending on the power supply voltage used for the comparator IC1), and when Vdiv is less than ground, the comparator output Cout goes low (e.g., 0V, or −5V, or −12V, etc.). As a result, the comparator IC1 effectively acts as a digital quantizer.

The system 300 also comprises an analysis circuit (in this example, the Micro Controller Unit, MCU, 370) that is coupled to the output of the comparator IC1 and configured to perform digital analysis using the output signal Cout. Whilst the term “MCU” is used throughout this disclosure as a synonym for analysis circuit, it should be appreciated that any suitable circuitry/processing means may be used to perform the described functionality, for example dedicated circuitry, programable logic such as FPGAs, application specific integrated circuits (ASICs) and/or processors such as micropressors arranged to executed software instructions to perform the described functionality.

FIG. 3B shows a representation of how Cout changes with Vdiv. As can be seen, when Vdiv is greater than ground, Cout goes high, and when Vdiv is less then ground, Cout goes low. However, if the magnitude of Vdiv changes, which is represented by the dotted waveform in FIG. 3B, this will not be reflected in Cout.

The system 300 may be effective for determining whether or not a voltage is present on the conductor 220, for example whether or not the switch S1 is open or closed. It is also a very simple, low cost system, since the components of the comparison circuit 310 are relatively low cost. However, its functionality is limited, since characteristics of Vdiv, such as magnitude and/or signal shape cannot be ascertained. There are many applications of non-contact voltage measurement where more than mere voltage detection is required. For example, for power distribution units (PDUs), energy metering, wiring systems, etc. it may be useful to know more about the frequency and/or phase and/or magnitude and/or signal shape of Vwire.

More complex and accurate circuits may be used to determine characteristics such as magnitude and/or signal shape, but those would typically be more expensive (for example, requiring more complex circuits and operation, higher power consumption, more expensive components, higher data requirements, etc.).

Recognising a desire to sense more characteristics of Vwire, without significantly increasing complexity, power, cost and/or data requirements, the inventors have developed the new systems described below.

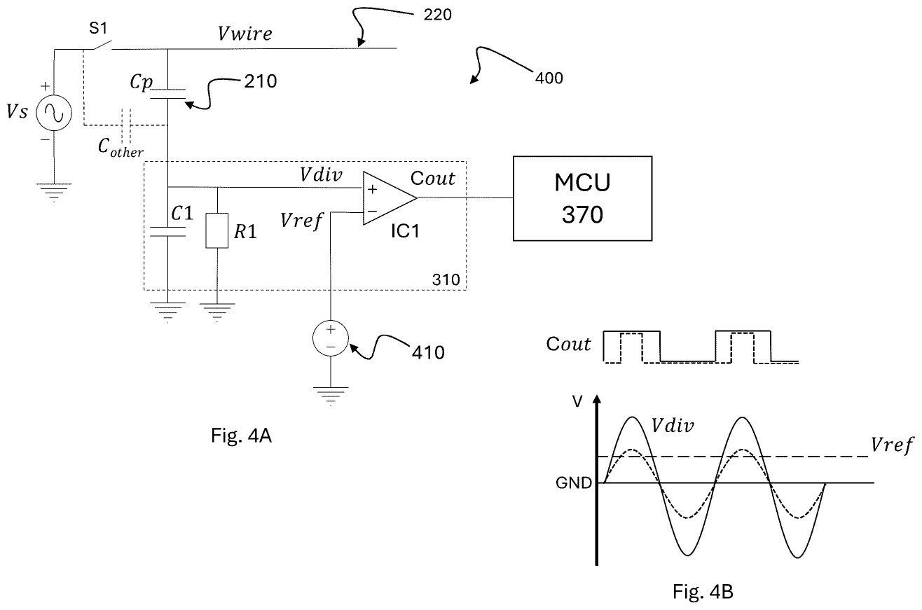

FIG. 4A shows an example system 400, in accordance with an aspect of the present disclosure. The system 400 is similar to system 300, but further comprises a reference voltage generator 410 coupled to the second input of the comparator IC1. The reference voltage generator 410 is configured to generate a reference voltage Vref, which is different to ground (for example, it is non-zero). As a result, the comparator IC1 compares Vdiv against Vref, with Cout reflecting whether Vdiv is above or below Vref (for example, going high when Vdiv is greater than Vref, and going low when Vdiv is less than Vref).

FIG. 4B shows the effect of this. As can be seen, when Vdiv has a larger magnitude (represented by the solid line waveform in the voltage plot), Cout is high for longer compared with when Vdiv has a smaller magnitude (represented by the dotted lines in the two plots). As a result, the MCU 370 may be configurable to use Cout to sense some magnitude related characteristics of the Vdiv. For example, the duty cycle ratio of Cout (i.e., the ratio of time during which Cout is high and time during which Cout is low) may imply some magnitude related information. For example, if the ratio of Cout high:Cout low is very small (e.g., if Cout is high for only a very short period of time compared with when it is low), it may be inferred that the peak magnitude of Vdiv is very similar to Vref. If the duty cycle ratio of Cout is close to 50:50, it may be inferred that Vdiv is much larger than Vref.

Furthermore, since Vdiv is dependent on Vwire (for example, substantially proportional), the frequency and/or duty cycle of Cout may be used by the MCU 370 to infer the frequency and/or phase of the signal on Vwire (for example, the phase relative to some fixed reference, or relative to a sensed signal on another conductor, such as another of the branch conductors represented in FIG. 1). For example, and as explained in more detail later, the voltage sensing techniques described herein may be used to sense the voltages on two or more different conductors, each of which may be supplied by the same or different phase of a multi-phase supply, and their relative phases may be characterised from the sensed voltages. Knowing the phase of a particular conductor 220 in a multi-conductor supply system such as that of FIG. 1 may be extremely valuable, to allow the user to know which phase each load is connected to. This can help with balancing the load on each phase.

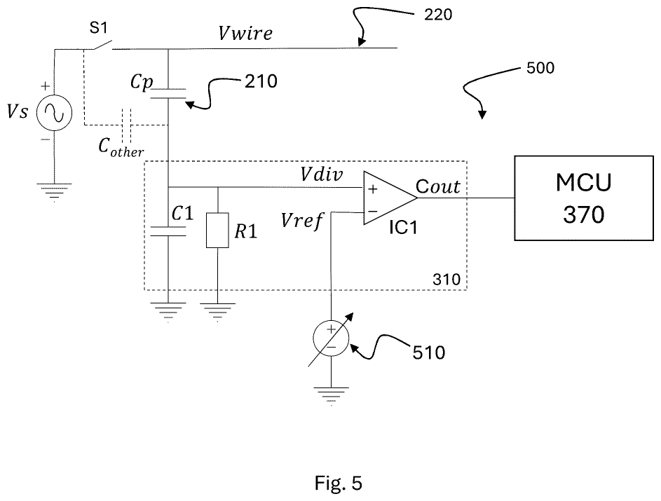

FIG. 5 shows a further example system 500 in accordance with an aspect of this disclosure. In this example, a reference voltage generator 510 is coupled to the second input of the comparator IC1 and configured to generate a variable reference voltage Vref. The reference voltage generator 510 may be implemented, and controlled, in any suitable way. For example, it may comprise a single reference voltage input and a potential divider arranged to divide the reference voltage input into one or more further references that are each switchably connectable to the reference voltage generator output.

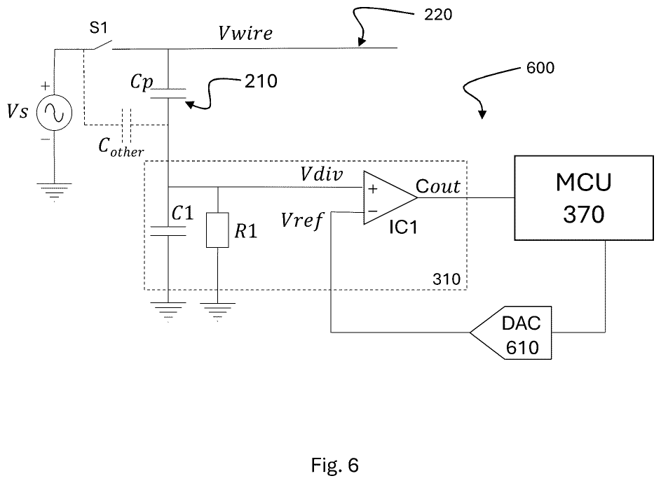

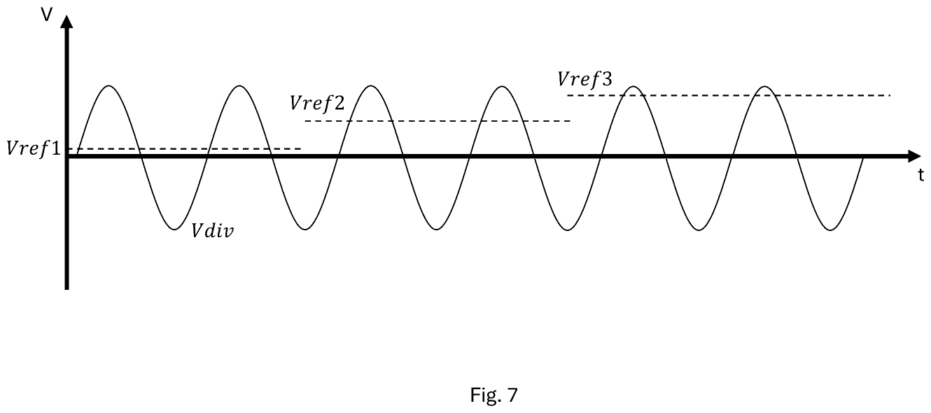

FIG. 6 shows a system 600 wherein the reference voltage generator is implemented by a digital to analog converter (DAC) 610. In this example, the MCU 370 is configured to control Vref by setting a digital value that is supplied to the input of the DAC 610. The DAC 610 then converts the digital value to a corresponding analog value, which is Vref. As a result, a highly controllable, relatively high resolution variable Vref may be achieved. The skilled person will appreciate that any suitable type of DAC, with any suitable resolution, may be used. Whilst in this example a single unit/circuit MCU 370 controls the reference voltage generator (the DAC 610) and performs the analysis described below, it will be appreciated that in practice these functions may be divided between two or more different circuits/units. However, any combination of one or more different circuits that together perform the functionality of controlling the reference voltage generator and performing the analysis described below should be understood as corresponding to the analysis circuit (MCU 370) described herein.

Whilst some specific examples of voltage reference generators 510 are given above, the skilled person will appreciated numerous other ways in which a variable reference voltage may be generated and controlled, for example by the MCU 370 or any other suitable component/device/controller.

FIGS. 7 to 9 show a graphical representation of how the variable reference voltage Vref of FIGS. 5 and 6 may be used to sense characteristics of Vdiv, and by extension Vwire.

FIG. 7 shows a representation of the AC signal Vdiv and three different reference voltage levels, Vref1, Vref2 and Vref3. The system 500, 600 may be configured such that Vref is set to any one of these voltage levels (such as Vref1) for a first period of time. Vref may then be set to another of the voltage levels (such as Vref2) for a second period of time. This may be repeated any number of times, for any number of different reference voltage levels, with each period of time having any suitable duration (for example, a duration approximately equal to 1/f, 10/f, 100/f, 300/f, etc. where f is the approximate expected frequency of Vdiv). The MCU 370 may be configured to sense Vdiv (and by extension Vwire) based on Cout during the first period of time, the second period of time, etc.

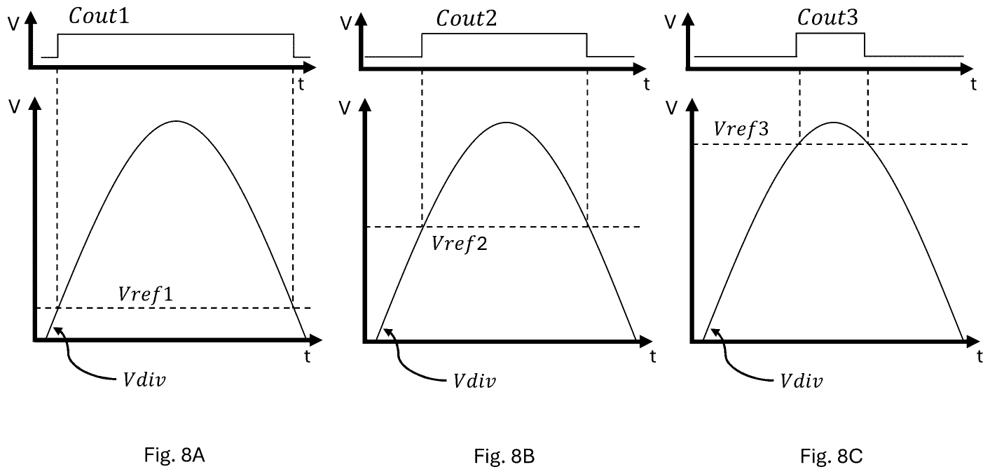

FIG. 8A shows part of a first period of time, during which Vref is set to a first voltage Vref1. For example, the MCU 370 may be configured to apply a first digital value to the input of the DAC 610 for the first period of time. The figure also represents the resulting shape/duty cycle of Cout, which is shown as Cout1.

FIG. 8B shows part of a second period of time, during which Vref is set to a second voltage Vref2. For example, the MCU 370 may be configured to apply a second digital value to the input of the DAC 610 for the second period of time. The figure also represents the resulting shape/duty cycle of Cout, which is shown as Cout2. As can be seen, in this example, Cout2 is high for less time than Cout1.

FIG. 8C shows part of a third period of time, during which Vref is set to a third voltage Vref3. For example, the MCU 370 may be configured to apply a third digital value to the input of the DAC 610 for the third period of time. The figure also represents the resulting shape/duty cycle of Cout, which is shown as Cout3. As can be seen, in this example, Cout3 is high for less time than Cout2.

Each of the first period, second period and third period of time may be set to any suitable duration. For example, a longer duration may result in a more accurate determination of the frequency and/or phase and/or duty cycle of each of Cout1, Cout2 and Cout3, but will take more time and have greater processing requirements. Therefore, the duration of each of the first period, second period and third period of time may be set in consideration of the desired level of accuracy, speed and processing requirements.

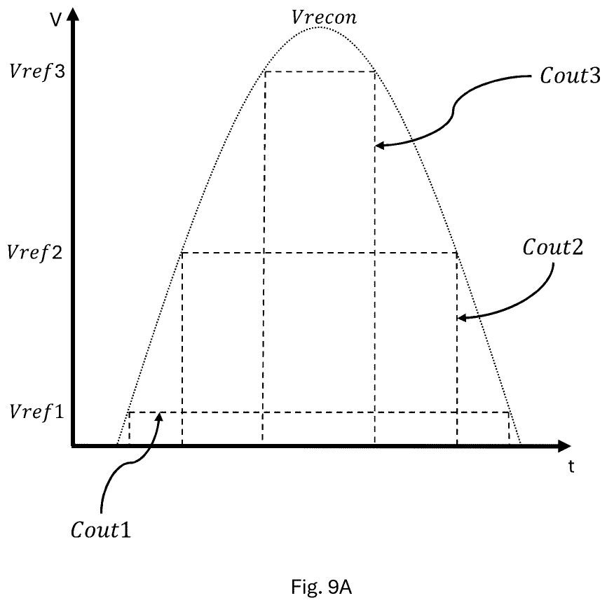

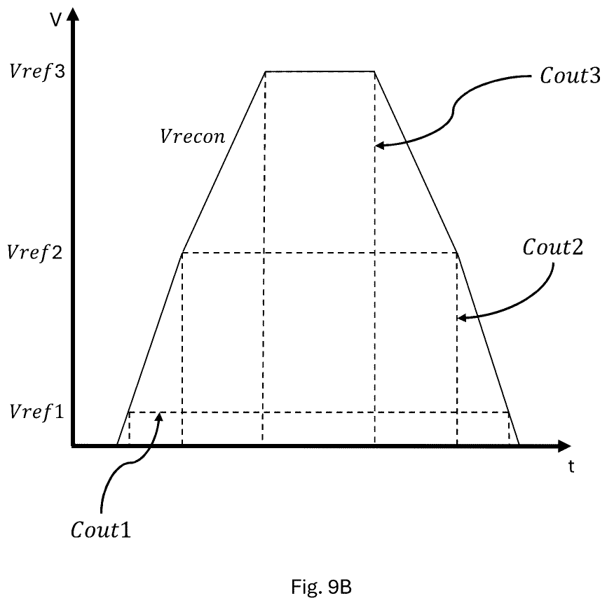

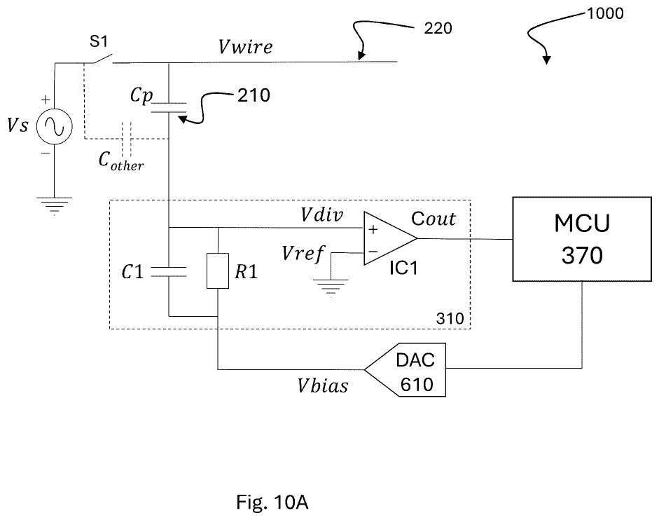

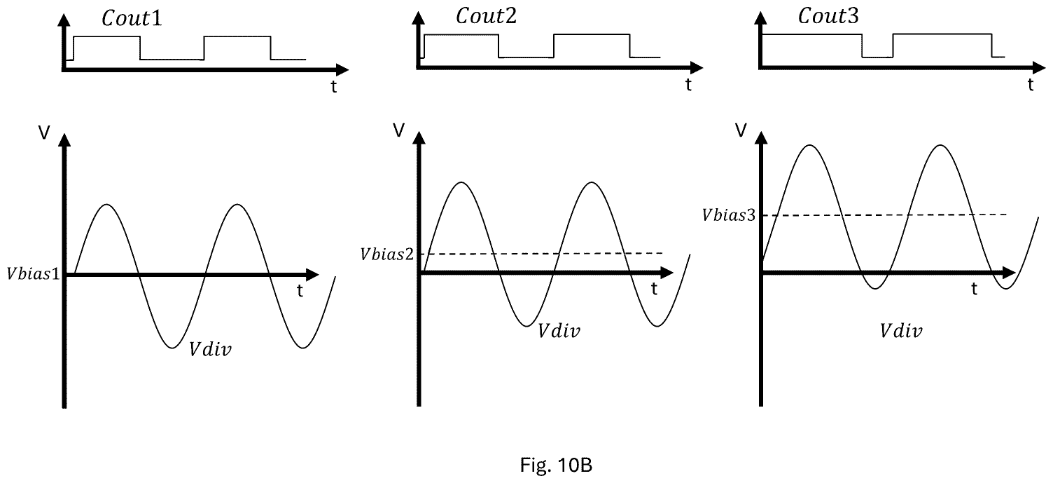

FIG. 9A shows how Cout1, Cout2, Cout3, Vref1, Vref2 and Vref3 may be used by the MCU 370 to characterise/measure Vdiv (and by extension Vwire). For example, by using timing/phase and/or duty cycle information for each of Cout1, Cout2 and Cout3 (e.g., by determining the transition timing for each of the signals and/or the amount of time for which each signal is high and low and/or the ratio/duty cycle between high:low for each signal), it is possible to effectively superimpose each of Cout1, Cout2, Cout3, along with the corresponding voltage levels Vref1, Vref2 and Vref3. By doing so, the MCU 370 may digitally generate a reconstructed version of Vdiv, which is shown in the Figure as Vrecon. By extension, Vrecon may also be seen as a reconstructed version of Vwire, at least for the purposes of characterising the frequency and/or phase of Vwire, but also to some extent for characterising the magnitude since Vdiv should be proportional to Vwire.

FIG. 9A shows Vrecon having a particular shape, which may be achieved by applying suitable fitting algorithms, to interpolate between the vertices of the overlayed Cout1, Cout2, Cout3, scaled to their corresponding voltage levels Vref1, Vref2 and Vref3. However, more straightforward fitting algorithms may be used which might result in a cruder reconstruction of Vdiv, but still with sufficient accuracy for some Vdiv/Vwire characterisation purposes.

FIG. 9B shows an example of a simple, straight-line interpolation technique to generate a cruder Vrecon. The skilled person will appreciate that various other types of fitting and interpolation techniques may be used to generate a reconstruction of Vdiv (and by extension Vwire).

The amplitude and/or phase and/or frequency of Vrecon can be used for further processing and insights relating to Vdiv and Vwire that are of greater accuracy and precision than can be achieved by the systems of FIGS. 3 and 4, without any significant increase in cost or complexity. As a result, the range and accuracy of characteristics of Vwire that can be sensed is much increased, without any significant increase in cost or complexity.

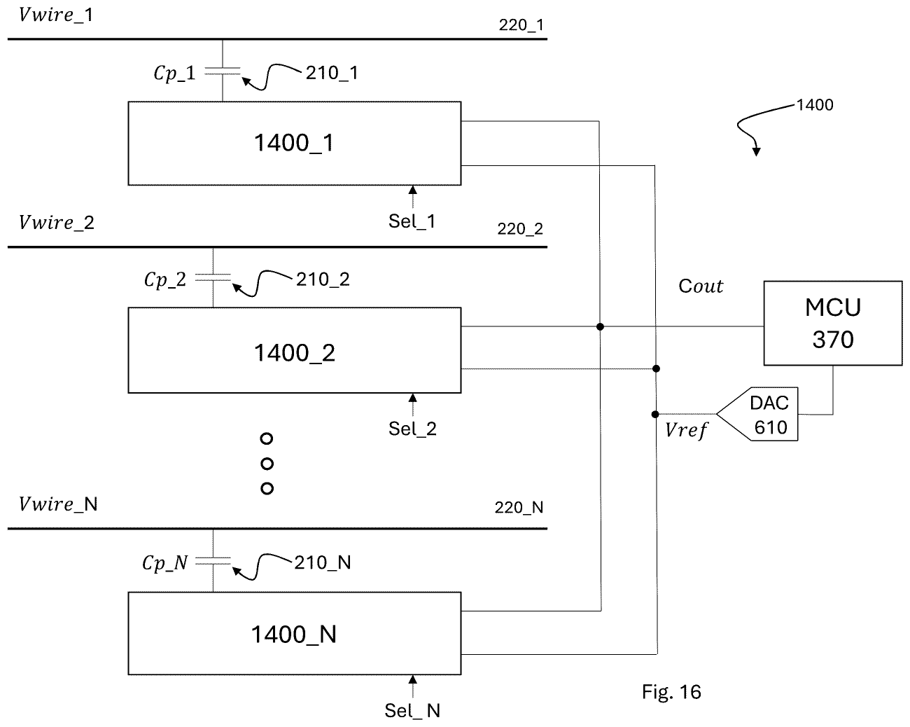

The ratio of the impedance divider may be unknown, or at least not accurately known, not least because the size of Cp may be variable depending on the diameter and/or material of the conductor 220, the thickness and/or material of the insulator 225, the distance and positioning between the conductive sense component 210 and the conductor 220, etc. As a result, characterisation/measurement of the magnitude (for example, the peak amplitude, mean, RMS, etc.) of Vdiv may not directly provide an accurate characterisation/measurement of the magnitude of Vwire. However, there are ways in which the reconstructed waveform Vrecon may be calibrated to provide a characterisation of the magnitude of Vwire. For example, the size of Cp and/or Cother, and therefore the ratio of Vwire to Vdiv, may be determined in a number of different ways. For example, during system test or calibration, it may be possible make a galvanic contact with the conductor 220 and directly measure the magnitude (peak amplitude, mean, RMS, etc.) of Vwire, and compare it to the magnitude of Vdiv, as determined using the techniques described with reference to FIGS. 5 to 9. In this way, a calibration value (e.g., a ratio) between the two may be determined. After testing/installation, the galvanic contact may be removed and the magnitude of Vwire characterised/measured by using the above described techniques to characterise/measure Vdiv and scale it using the previously determined calibration value. In a further example, a galvanic voltage measurement circuit may be available elsewhere in the wider power installation, such as the voltage measurement arrangement 150, 160 of FIG. 1, which may be used in real-time to calibrate/scale Vrecon to Vwire, so that the magnitude of Vwire can be characterised. An example of this is described later, with reference to FIG. 16.

In any event, regardless of whether or not the magnitude of Vwire can be sensed from the reconstruction of Vdiv, the frequency and/or phase of Vwire and Vdiv should be substantially the same. Consequently, the frequency and/or phase of Vdiv and Vwire can be sensed from the frequency and/or phase of Vrecon, even if Vrecon is generated using crude interpolation/extrapolation techniques, such as those of FIG. 9B.

FIG. 10A shows a further example system 1000 in accordance with an aspect of this disclosure. The system 1000 is very similar to the system if FIG. 6, but in this example a reference voltage, identified as Vbias, is applied to the impedance divider, specifically to the second terminal of the impedance component, capacitor C1 and/or resistor R1, (i.e., the terminal not coupled to the conductive sense component 210). In an alternative implementation, Vbias may be applied to the second terminal of R1, with the second terminal of C1 being coupled to a different fixed reference, such as ground. Whilst in this example the reference voltage generator is referenced as a DAC 610, it will be appreciated that Vbias may be generated using any suitable type of reference voltage generator.

By biasing the potential divider with Vbias in this way, the centre point about which Vdiv alternates can be moved, which enables Cout to be used for sensing Vdiv (and by extension Vwire) in a similar way to that described earlier.

FIG. 10B shows an example graphical representation of Vdiv and the corresponding Cout for three different values of Vbias. In this example, Vbias1 is set to 0V, and Vbias2 and Vbias3 are set to different, non-zero positive voltages. For each different value of Vbias it can be seen that the corresponding duty cycle ratio and timing of Cout—i.e., Cout1, Cout2 and Cout3—changes. Consequently, applying each of two or more different values of Vbias for a respective period of time results in two or more different Cout signals that can be used to characterise/measure the phase and/or magnitude of Vdiv (and therefore Vwire), in the same ways as explained earlier.

Whilst in the examples of FIGS. 4, 5 and 10, the values of Vref and Vbias are all positive (or zero), optionally one or more of the values of Vref and Vbias may be set to negative values, if the reference voltage generator is one that is capable of setting negative voltages. By utilising both positive and negative voltage values for Vref and Vbias it may be possible to more accurately reconstruct Vdiv and characterise Vdiv and Vwire, for example enabling more accurate peak-to-peak reconstruction of Vdiv, and therefore a more accurate determination of peak-to-peak signal characteristics, such as peak-to-peak magnitude.

However, the inventors have recognised that including within the system a reference voltage generator that is capable of generating negative voltages may increase the cost and complexity of the system. Therefore, they have developed implementations of the system that enable more than 50% (and potentially all) of the Vwire signal to be sensed and accurately reconstructed, without requiring negative reference voltages.

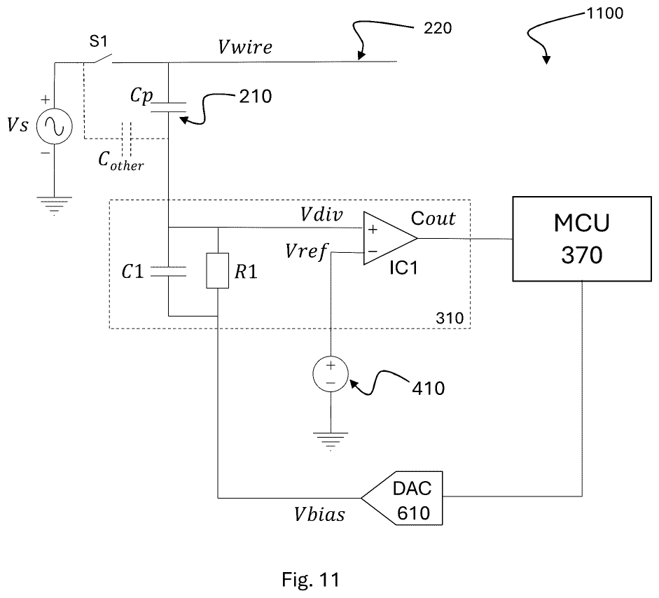

FIG. 11 shows an example system 1100 that enables such functionality. The system 1100 is effectively a merging of the systems of FIGS. 4 and 10, wherein a fixed reference voltage Vref is applied to the second input of the comparator IC1, and a variable reference voltage Vbias is applied to the impedance divider (either to both C1 and R1, as shown in the Figure, or just to R1).

Operation of the system 1100 is very similar to that represented by FIG. 10B, except that the comparison performed by the comparator IC1 is the biased Vdiv against a positive voltage Vref (rather than the biased Vdiv against ground, as shown in FIG. 10B). As a result, Vdiv and Vref may be set at appropriate relative values to enable more flexibility and range in sensing Vdiv (and by extension Vwire), enabling more accurate reconstruction and signal characterisation.

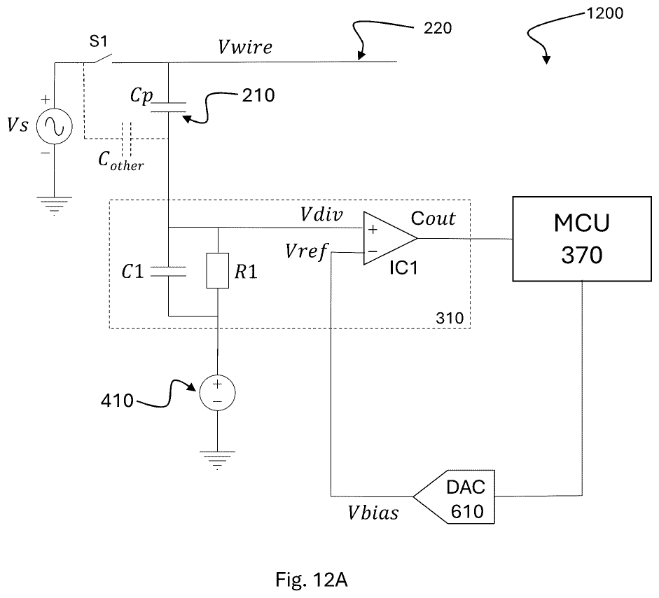

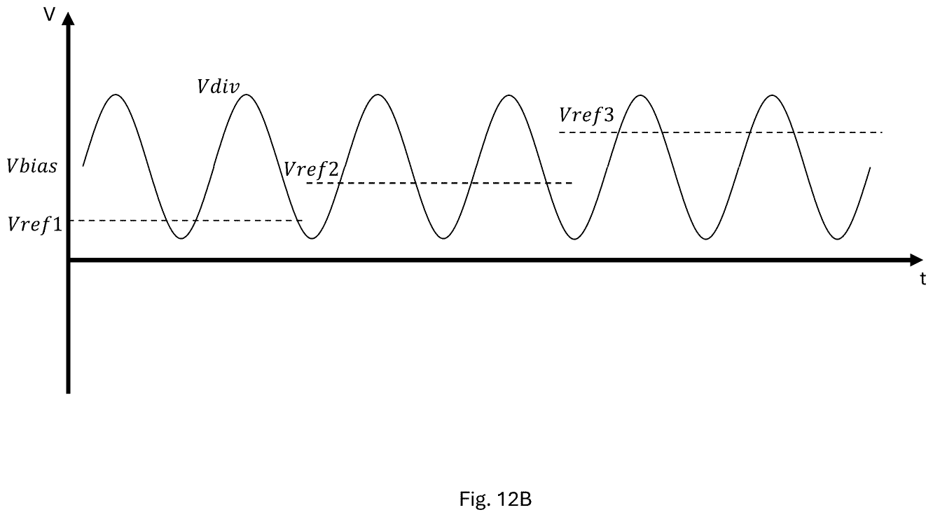

FIG. 12A shows a further example system 1200 that is very similar to system 1100, except that Vref is a variable reference voltage and Vbias is a fixed voltage that biases Vdiv.

FIG. 12B shows an example representation of Vdiv biased by Vbias, and three different levels at which Vref may be set-Vref1, Vref2 and Vref 3. In this example, Vbias is set at a level that is greater than the expect peak amplitude of Vidv, such that Vbias+Vdiv is always greater than zero. As a result, Vref may be set to a variety of different positive voltage levels and used to sense the entirety of Vdiv, such that the entire Vdiv signal (and by extension the entire Vwire signal) may be accurately reconstructed and characterised.

In the examples of FIGS. 11 and 12, one fixed reference voltage and one variable reference voltage is applied to the circuit 310. In an alternative, both Vbias and Vref could be made variable. This may enable even greater levels of control and flexibility in sensing and characterising Vdiv and Vwire. For this purpose, the system may comprise two reference voltage generators, such as two DACs, one for controllably generating Vbias and the other for controllably generating Vref.

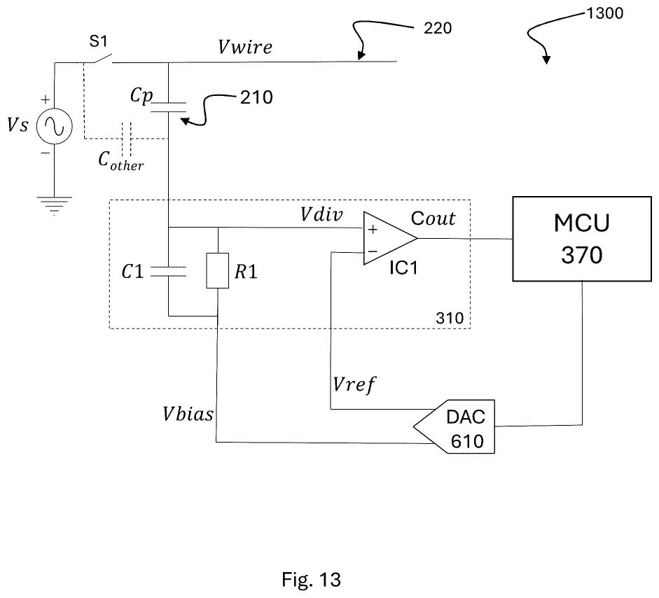

FIG. 13 shows an alternative example system 1300 where Vref and Vbias are both variable. In this example, DAC 610 is a differential DAC in that it outputs the analog conversion as a differential signal. The differential analog signal is made up of two analog signals, the first one which is coupled to the second input of the comparator IC1, and therefore acts as variable reference voltage Vref, and the second one of which is coupled to the impedance divider and acts as a variable further reference voltage Vbias. As a result, a single reference voltage generator DAC 610 may be used to control two variable reference voltages. It will be appreciated that this is merely one example implementation, and the system 1300 may be implemented in any other suitable way to enabled two variable references to be generated and controlled.

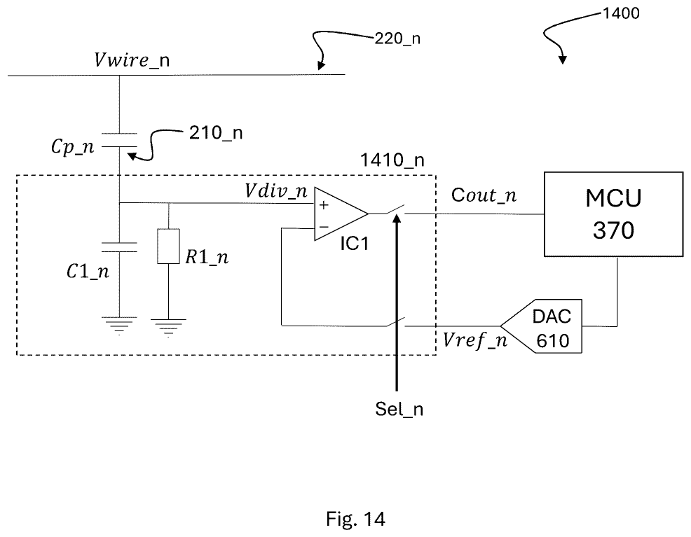

FIG. 14 shows part of an example system 1400 in accordance with an aspect of this disclosure. In this example, the system 1400 comprises a plurality of comparison circuits 1410_n, just one of which is represented in the Figure. Each comparison circuit 1410_n is coupled to a respective conductive sense component 210_n, so as to capacitively Cp_n couple to a respective conductor 220_n. Each comparison circuit 1410_n also comprises switches to enable switchable coupling to the MCU 370 and a reference voltage generator (in this example, the DAC 610). The switches are controlled by signal Sel_n, which may be set by the MCU 370 or by any other suitable control unit/device/circuit. As a result, when the switches of comparison circuit 1410_n are closed, the MCU 370 may sense Vwire_n in any of the ways described earlier.

Whilst the system 1400 corresponds with the implementation represented in FIG. 6, it may alternatively be configured as shown in any of FIGS. 4A, 5, 10A, 11, 12A and 13.

The system 1400 enables the sensing of Vwire_n using any of the earlier described techniques, but also enables a single MCU 370 and reference voltage generator to be used for sensing Vwire_n on two or more different conductors 220_n.

The switches in the comparison circuit 1410_n may be implemented in any suitable way, for example using transistors (such as FETs or bi-polar transistors), or relays, or any other controllable switch. Alternatively, rather than using switches, circuit 1410_n could be configured such that the select control signal Sel_n sets the comparator IC1 of all non-selected comparison circuits 1410_n to its high impedance state (i.e., its powered down state, where the comparator output goes to high impedance), such that those comparison circuits 1410_n are effectively put into a non-operational state, and set the comparator IC1 of the selected comparison circuit 1410_n to a low-impedance state (i.e., its powered up state, where the comparator output goes to low impedance), such that that selected circuit 1410_n is effectively put into an operational state.

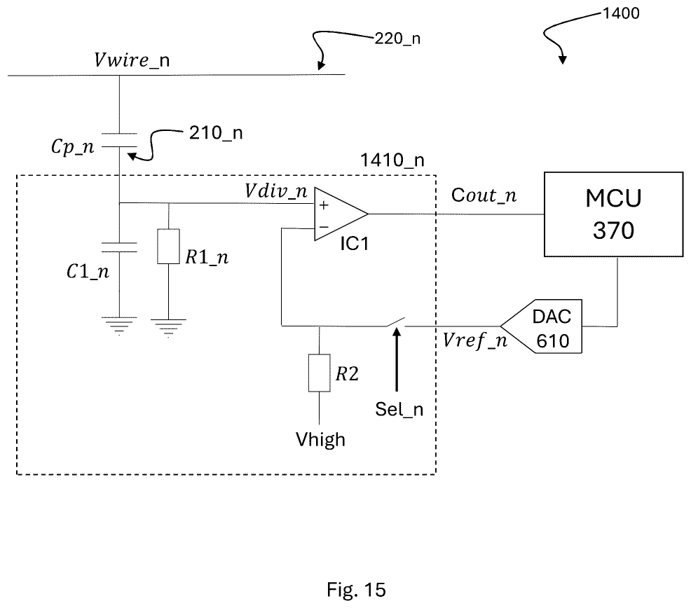

FIG. 15 shows a further example implementation of system 1400 that comprises an alternative implementation of the comparison circuit 1410_n. In this example, there is no switch at the output of the comparator IC1, and IC1 is an open drain output comparator. Instead, a “pull-up” resistor R2 (which may be relatively high impedance, such as in the 100s of kOhm range, or in the MOhm range) couples the inverting input of the comparator IC1 to a relatively high voltage Vhigh, such as the VDD supply voltage of the comparator IC1, that is greater than the expected maximum voltage of Vdiv_n. By doing so, for all comparison circuits 1410_n where Vref_n is decoupled by Sel_n setting the switch to an open state, the inverting input to the comparator IC1 will be pull high such that the output of the comparator IC1 will be in an open state (e.g., high impedance). For the single one of the comparison circuits 1410_n where Sel_n is controlled to close the switch, Vref_n will effectively overpower “pull-up” resistor R2, and set the potential at the inverting input of the comparator IC1 to equal Vref_n. That selected comparison circuit 1410_n will then operate as described earlier. By implementing the comparison circuits 1410_n in this way, it may be possible to multiplex the comparison circuits 1410_n and use a single MCU 370 and DAC 610, with half the number of controllable switches compared with the example of FIG. 14. In an alternative, if Vdiv is coupled to the inverting input of the comparator IC1 and Vref_n and R2 are coupled to the non-inverting input of the comparator IC1, then R2 may be a “pull-down” resistor coupled to a relatively low voltage (e.g., a negative supply voltage) rather than Vhigh.

FIG. 16 shows an expanded view of the system 1400. In this system, there are N conductors 220_n and a corresponding N conductive sense components 210_n and comparison circuits 1410_n. At any given time, the select signal Sel_N may activate a selected one of the comparison circuits 1410_n, for example by closing the switches of the circuit in order to couple the selected comparison circuit 1410_n to the MCU 370 and the reference voltage generator (in this example, the DAC 610). The MCU 370 may control the DAC 610 to set Vref to appropriate levels, as explained earlier, so that the selected Vwire_n may be sensed and characterised. This may be serially repeated over time for different conductors 220_n, so that two or more voltages Vwire_n may be consecutively sensed using a single analysis circuit (MCU 370) and reference voltage generator (DAC 610). Optionally, if the comparison circuits 1410_n are implemented as shown in FIG. 15, then an additional resistor at the input to the MCU 370 that pulls the input high, unless one of the comparison circuits 1410_n is selected (as explained with reference to FIG. 15) and pulls the input low.

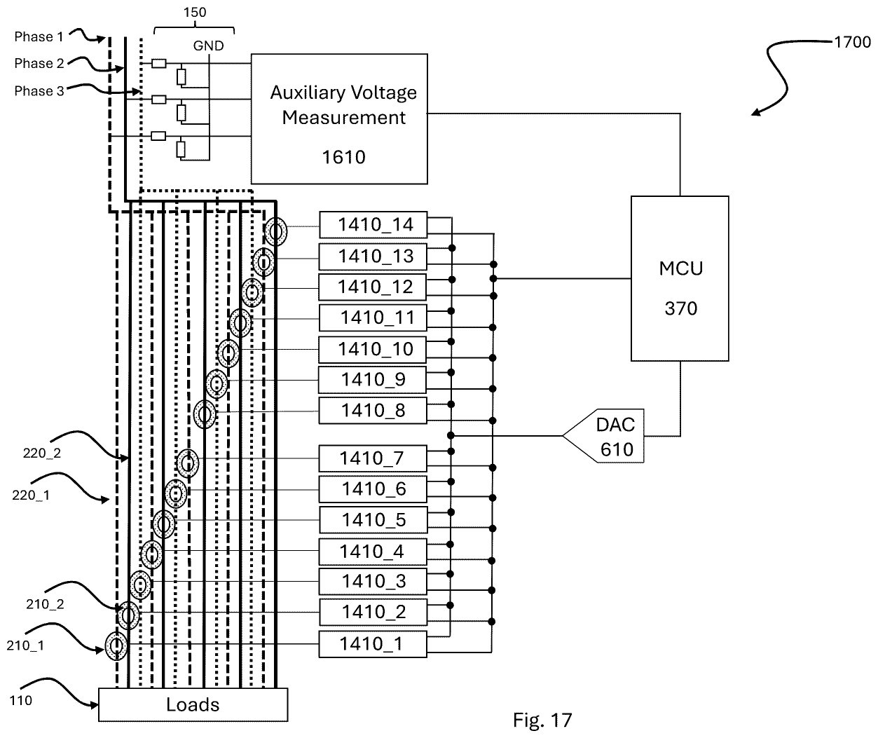

FIG. 17 shows an example system 1700 that incorporates system 1400 (the select signal lines have not been represented in FIG. 16, for the sake of clarity). As can be seen, this example system 1600 comprises 14 conductors 220 (only two of which, 220_1 and 220_2, are labelled), although it may alternatively comprise any number of conductors 220_n. The system 1600 also comprises a corresponding number of conductive sense components 210 (only two of which, 220_1 and 220_2, are labelled), and a corresponding number of comparison circuits 1410_1 to 1410_14. This example system is a three phase system, where each conductor 220 is a branch from one of the phases.

The system 1600 enables the MCU 370 to consecutively, serially sense the voltage V_wire for a plurality of the conductors 220. As a result, it may be possible to characterise the phase of each branch voltage (for example, the phase of the voltage on one conductor 220_n relative to the voltage on one or more other conductors) and/or the magnitude of each branch voltage. This may be very helpful for a number of reasons. For example, it may be very helpful to know which phase each sensed voltage is associated with, to identify the largest load on each phase, find the sum total load on each phase by adding each branch current associated with each phase (assuming each branch current is separately being measured, for example using current transducers as shown in FIGS. 1 and 2) and/or identifying incorrect wiring, such as incorrect phase rotation, or the use of a single phase in place of three phase.

Phase information for each sensed voltage may be extracted from reconstructions of the sensed voltages (for example, reconstructions generated as described with reference to FIGS. 8 and 9), such as by analysing the zero crossing timing of each reconstructed voltage signal and/or predicting/interpolating where the zero crossing point from the reconstructed voltage signal and/or using a Fourier Transform, such as an FFT, on the reconstructed voltage signal and/or using a CORDIC algorithm on the reconstructed voltage signal, etc.

System 1600 also optionally includes a circuit for galvanic voltage measurement of each phase, comprising an impedance divider network 150 and an auxiliary voltage measurement circuit 1610 (which may be the same as voltage measurement circuit 160). In this way, the magnitude of the voltage for each phase may be directly measured, for example as explained with reference to FIG. 1. If such measurements are available, they may be used by the MCU 370 to calibrate one or more of the reconstructed voltage signals that the MCU 370 generates. For example, the voltage magnitude measured by the auxiliary voltage measurement circuit 1610 for a particular phase may be used to calibrate the reconstructed Vwire signal for all conductors 220_n that have the same phase. In this, uncertainty about the correlation between magnitude of the reconstructed Vdiv and the magnitude of Vwire, which may be caused by a lack of precise knowledge of Cp and Cother, may be reduced or resolved entirely. Furthermore, the real, galvanic measurements of voltage performed at the “root” conductor, in this example, may be used to create a measured voltage signal for some or all of the phases, which can then be correlated with some or all of the sensed, reconstructed branch voltages. This may improve the accuracy and resolution of the voltage reconstructions. In an alternative, the auxiliary voltage measurement circuit 1610 may be configured to compare the measured voltage against at least one of a number of reference voltages Vref1′, Vref2′, Vref3′ etc., to order to generate at least one comparison signal Cout1′, Cout2′, Cout3′, etc. in a similar way to the systems described earlier. The values of Vref1′, Vref2′, Vref3′ etc. may be adjusted until the duty cycles of Cout1′, Cout2′, Cout3′, etc. substantially match the duty cycles of Cout1, Cout2, Cout3, etc. Since the shape of the voltage measured by the auxiliary measurement circuit 1610 and Vdiv should be substantially the same, the ratio of Vref1:Vref1′, Vref2:Vref2′, Vref3:Vref3′, etc. may be used for scaling the magnitude of Vrecon, such that it should accurately correspond to the magnitude of Vwire. For example, if Vref1:Vref1′ is found to be 1:2, then a factor of 2 may be applied to Vrecon such that it's magnitude correctly characterises the magnitude of Vwire.

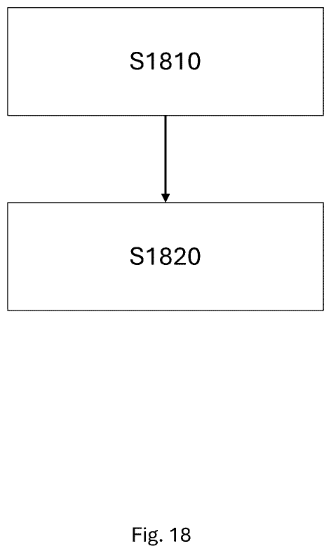

FIG. 18 shows the steps of an example method for sensing an AC voltage.

In Step S1810, a first potential at a first input of a comparator (e.g. IC1) is compared against a second potential at a second input of the comparator in order to generate a comparison signal (e.g. Cout) indicative of which of a first potential at the first input and a second potential at the second input is higher. The first input of the comparator is coupled to a first conductive sense component (e.g. 210) for positioning, when in use, in non-contacting proximity to a first conductor (e.g. 220) so as to capacitively couple with the first conductor to generate a first AC sensing signal at the first conductive sense component, wherein the first AC sensing signal is dependent on a first AC voltage of the first conductor. The first input of the comparator or the second input of the comparator is biased by a variable reference voltage (e.g. Vref or Vbias).

In Step S1820, the first AC voltage is sensed based on the variable reference voltage and the first comparison signal.

The terminology “coupled” used above encompasses both a direct electrical connection between two components, and an indirect electrical connection where the two components are electrically connected to each other via one or more intermediate components.

The skilled person will readily appreciate that various alterations or modifications may be made to the above described aspects of the disclosure without departing from the scope of the disclosure.

Whilst this disclosure is presented primarily in the context of multi-phase systems, and particularly energy measurement in multi-phase systems, it will be appreciated that the disclosed voltage sensing techniques are more broadly relevant and may be used in any other single or multi-phase context.

### ASPECTS OF THE DISCLOSURE

Non-limiting aspects of the disclosure are set out in the following numbered clauses:
1. A non-contact AC voltage sensing system comprising:
   a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor;
   a first comparison circuit comprising:
      a first comparator comprising:
         a first input coupled to the first conductive sense component;
         a second input, wherein either input of the first comparator is biased by a variable reference voltage applied to the first comparison circuit; and
         an output to output a first comparison signal indicative of which of a first potential at the first input and a second potential at the second input is higher; and
   an analysis circuit coupled to the output of the first comparator and configured to sense the first AC voltage based on the variable reference voltage and the first comparison signal.
2. The system of clause 1, wherein the analysis circuit is further configured to:
   set the variable reference voltage to a first reference voltage for a first period of time;
   set the variable reference voltage to a second reference voltage for a second period of time; and
   sense the first AC voltage based on the first comparison signal during the first period of time and the first comparison signal during the second period of time,
   wherein the first reference voltage is different to the second reference voltage.
3. The system of clause 2, wherein sensing the first AC voltage comprises: characterising at least one of a frequency and a phase of the first AC voltage.
4. The system of clause 2 or clause 3, wherein sensing the first AC voltage comprises:
   characterising a magnitude of the first AC voltage.
5. The system of clause 3 or clause 4, wherein sensing the first AC voltage comprises:
   determining whether the first AC voltage is driving a load or is floating.
6. The system of any of clauses 2 to 5, wherein sensing the first AC voltage comprises:
   generating at least one of: a reconstructed version of the first AC voltage signal; a reconstructed version of a signal at the first input of the first comparator.
7. The system of clause 6, further comprising:
   an auxiliary voltage measurement circuit coupled to the analysis circuit and configured to measure a related AC voltage and output a measurement of the related AC voltage to the analysis circuit;
   wherein generating the reconstructed first AC voltage signal is further based on the measurement of the related AC voltage, and
   wherein the related AC voltage is related to the first AC voltage.
8. The system of clause 7, wherein the related AC voltage is measured by the auxiliary voltage measurement circuit at a conductor that is conductively coupled to the first conductor.
9. The system of any preceding, further comprising a reference voltage generator to generate the variable reference voltage.
10. The system of clause 9, wherein the reference voltage generator comprises a digital to analog signal, DAC, configured to:
   receive a digital control signal from the analysis circuit; and
   generate the variable reference voltage by converting the digital control signal to an analog signal.
11. The system of any preceding clause, wherein the first comparison circuit comprises:
   a first impedance component having a first terminal coupled to the conductive sense component.
12. The system of clause 11, wherein the first impedance component comprises a second terminal coupled to the variable reference voltage, and
   wherein the second input of the first comparator is coupled to a further reference voltage.
13. The system of clause 12, wherein the first impedance component comprises a second terminal coupled to a further reference voltage, and
   wherein the reference voltage generator is coupled to the second input of the first comparator.
14. The system of clause 12 or clause 13, wherein the further reference voltage is ground or a fixed reference voltage.
15. The system of clause 12 or clause 13, wherein the further reference voltage is variable, and
   wherein the analysis circuit is further configured to set the further reference voltage.
16. The system of clause 15, further comprising a reference voltage generator to generate the variable reference voltage and the further reference voltage.
17. The system of clause 16, wherein the reference voltage generator comprises a differential digital to analog converter, DAC, configured to:
   receive a digital control signal from the analysis circuit; and
   generate the differential analog signal by converting the digital control signal to a differential analog signal,
   wherein the differential analog signal is made up of first analog signal and a second analog signal, and
   wherein the first analog signal is the variable reference voltage and the second analog signal is the further reference voltage.
18. The system of any of clauses 11 to 17, wherein the first impedance component comprises at least one of a resistor and a capacitor.
19. The system of any preceding clause, further comprising:
   a second conductive sense component for positioning, when in use, in non-contacting proximity to a second conductor so as to capacitively couple with the second conductor to generate a second AC sensing signal at the second conductive sense component, wherein the second AC sensing signal is dependent on a second AC voltage of the second conductor;
   a second comparison circuit comprising:
      a second comparator comprising:
         a first input coupled to the second conductive sense component;
         a second input; and
         an output to output a second comparison signal indicative of which of a first potential at the first input and a second potential at the second input is higher,
   wherein the analysis circuit is coupled to the output of the second comparator and configured to sense the second AC voltage based on the second comparison signal.
20. The system of clause 19, wherein the variable reference voltage biases any one of: the first potential at the first input of the second comparator, such that the first potential comprises the second AC sensing signal and a bias voltage; the second potential at the second input of the second comparator, such that the second potential comprises the bias voltage,
   wherein the bias voltage is dependent on the variable reference voltage.
21. A method for sensing an AC voltage, the method comprising:
   comparing a first potential at a first input of a comparator against a second potential at a second input of the comparator in order to generate a comparison signal indicative of which of a first potential at the first input and a second potential at the second input is higher,
      wherein the first input of the comparator is coupled to a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor, and
      wherein either the first input of the comparator or the second input of the comparator is biased by a variable reference voltage, and the method further comprises:
   sensing the first AC voltage based on the variable reference voltage and the first comparison signal.
22. The method of clause 21, further comprising:
   setting the variable reference voltage to a first reference voltage for a first period of time;
   setting the variable reference voltage to a second reference voltage for a second period of time; and
   sensing the first AC voltage based on the first comparison signal during the first period of time and the first comparison signal during the second period of time,
   wherein the first reference voltage is different to the second reference voltage.
23. The method of clause 22, wherein sensing the first AC voltage comprises:
   generating at least one of: a reconstructed version of the first AC voltage signal; a reconstructed version of a signal at the first input of the first comparator.
24. The method of clause 22 or clause 23, wherein sensing the AC voltage is based on at least one of:
   the first reference voltage and a duty cycle of the first comparison signal during the first period of time;
   the second reference voltage and a duty cycle of the first comparison signal during the second period of time
25. A circuit comprising:
   a comparison circuit comprising:
      a comparator comprising:
         a first input suitable for coupling to a conductive sense component, wherein the conductive sense component is suitable for capacitive coupling to a conductor having an AC voltage;
         a second input, wherein the first input or the second input is biased by a variable reference voltage applied to the comparison circuit; and
         an output to output a comparison signal indicative of which of a first potential at the first input and a second potential at the second input is higher; and
   an analysis circuit coupled to the output of the comparator and configured to:
      set the variable reference voltage; and
      sense the AC voltage based on the variable reference voltage and the comparison signal.

1. A non-contact AC voltage sensing system comprising:
a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor;
a first comparison circuit comprising:
a first comparator comprising:
a first input coupled to the first conductive sense component;
a second input, wherein either input of the first comparator is biased by a variable reference voltage applied to the first comparison circuit; and
an output to output a first comparison signal indicative of which of a first potential at the first input and a second potential at the second input is higher; and
an analysis circuit coupled to the output of the first comparator and configured to sense the first AC voltage based on the variable reference voltage and the first comparison signal.

2. The system of claim 1, wherein the analysis circuit is further configured to:
set the variable reference voltage to a first reference voltage for a first period of time;
set the variable reference voltage to a second reference voltage for a second period of time; and
sense the first AC voltage based on the first comparison signal during the first period of time and the first comparison signal during the second period of time,
wherein the first reference voltage is different to the second reference voltage.

3. The system of claim 2, wherein sensing the first AC voltage comprises:
characterising at least one of a frequency and a phase of the first AC voltage.

4. The system of claim 2, wherein sensing the first AC voltage comprises:
characterising a magnitude of the first AC voltage.

5. The system of claim 2, wherein sensing the first AC voltage comprises:
generating at least one of: a reconstructed version of the first AC voltage signal; a reconstructed version of a signal at the first input of the first comparator.

6. The system of claim 5, further comprising:
an auxiliary voltage measurement circuit coupled to the analysis circuit and configured to measure a related AC voltage and output a measurement of the related AC voltage to the analysis circuit;
wherein generating the reconstructed first AC voltage signal is further based on the measurement of the related AC voltage, and
wherein the related AC voltage is related to the first AC voltage.

7. The system of claim 1, further comprising a reference voltage generator to generate the variable reference voltage.

8. The system of claim 7, wherein the reference voltage generator comprises a digital to analog signal, DAC, configured to:
receive a digital control signal from the analysis circuit; and
generate the variable reference voltage by converting the digital control signal to an analog signal.

9. The system of claim 1, wherein the first comparison circuit comprises:
a first impedance component having a first terminal coupled to the conductive sense component.

10. The system of claim 9, wherein the first impedance component comprises a second terminal coupled to the variable reference voltage, and
wherein the second input of the first comparator is coupled to a further reference voltage.

11. The system of claim 10, wherein the first impedance component comprises a second terminal coupled to a further reference voltage, and
wherein the reference voltage generator is coupled to the second input of the first comparator.

12. The system of claim 10, wherein the further reference voltage is variable, and
wherein the analysis circuit is further configured to set the further reference voltage.

13. The system of claim 12, further comprising a reference voltage generator to generate the variable reference voltage and the further reference voltage.

14. The system of claim 13, wherein the reference voltage generator comprises a differential digital to analog converter, DAC, configured to:
receive a digital control signal from the analysis circuit; and
generate the differential analog signal by converting the digital control signal to a differential analog signal,
wherein the differential analog signal is made up of first analog signal and a second analog signal, and
wherein the first analog signal is the variable reference voltage and the second analog signal is the further reference voltage.

15. The system of claim 1, further comprising:
a second conductive sense component for positioning, when in use, in non-contacting proximity to a second conductor so as to capacitively couple with the second conductor to generate a second AC sensing signal at the second conductive sense component, wherein the second AC sensing signal is dependent on a second AC voltage of the second conductor;
a second comparison circuit comprising:
a second comparator comprising:
a first input coupled to the second conductive sense component;
a second input; and
an output to output a second comparison signal indicative of which of a first potential at the first input and a second potential at the second input is higher,
wherein the analysis circuit is coupled to the output of the second comparator and configured to sense the second AC voltage based on the second comparison signal.

16. A method for sensing an AC voltage, the method comprising:
comparing a first potential at a first input of a comparator against a second potential at a second input of the comparator in order to generate a comparison signal indicative of which of a first potential at the first input and a second potential at the second input is higher,
wherein the first input of the comparator is coupled to a first conductive sense component for positioning, when in use, in non-contacting proximity to a first conductor so as to capacitively couple with the first conductor to generate a first AC sensing signal at the first conductive sense component, wherein the first AC sensing signal is dependent on a first AC voltage of the first conductor, and
wherein either the first input of the comparator or the second input of the comparator is biased by a variable reference voltage, and the method further comprises:
sensing the first AC voltage based on the variable reference voltage and the first comparison signal.

17. The method of claim 16, further comprising:
setting the variable reference voltage to a first reference voltage for a first period of time;
setting the variable reference voltage to a second reference voltage for a second period of time; and
sensing the first AC voltage based on the first comparison signal during the first period of time and the first comparison signal during the second period of time,
wherein the first reference voltage is different to the second reference voltage.

18. The method of claim 17, wherein sensing the first AC voltage comprises:
generating at least one of: a reconstructed version of the first AC voltage signal; a reconstructed version of a signal at the first input of the first comparator.

19. The method of claim 17, wherein sensing the AC voltage is based on at least one of:
the first reference voltage and a duty cycle of the first comparison signal during the first period of time;
the second reference voltage and a duty cycle of the first comparison signal during the second period of time

20. A circuit comprising:
a comparison circuit comprising:
a comparator comprising:
a first input suitable for coupling to a conductive sense component, wherein the conductive sense component is suitable for capacitive coupling to a conductor having an AC voltage;
a second input, wherein the first input or the second input is biased by a variable reference voltage applied to the comparison circuit; and
an output to output a comparison signal indicative of which of a first potential at the first input and a second potential at the second input is higher; and
an analysis circuit coupled to the output of the comparator and configured to:
set the variable reference voltage; and
sense the AC voltage based on the variable reference voltage and the comparison signal.
